(19) United States
(12) Patent Application Publication
(10) Pub. No.: US 2016/0183402 A1
(43) Pub. Date: Jun. 23, 2016

(54) REDUCING TRACE LENGTH AND INSERTION LOSS OF HIGH SPEED SIGNALS ON A NETWORK SWITCH BOARD

(71) Applicant: Intel Corporation, Santa Clara, CA (US)

(72) Inventors: Vladimir Tamarkin, Huntingdon Valley, PA (US); William F. Federer, West Chester, PA (US); Thomas W. Genetti, Weatherly, PA (US)

(21) Appl. No.: 14/581,962

(22) Filed: Dec. 23, 2014

(51) Int. Cl. H05K 7/14; H04L 12/935

(52) U.S. Cl. CPC H05K 7/1492; H05K 7/1489; H04L 49/30

(57) ABSTRACT

An electrical device can include a printed circuit board (PCB), an electrical component integrated therewith, and connectors that are each integrated with a certain edge of the PCB. Traces can provide electrical channels between the connectors and the electrical component. Some of the connectors can be integrated at a first edge of the PCB and within a first plane, and other connectors can be integrated at a second edge of the PCB and within a second plane that is distinct from the first plane.

### TECHNICAL FIELD

The disclosed technology relates generally to network switch devices and, more particularly, to high speed traces integrated with network switch boards.

### BACKGROUND

Network switch boards generally have a number of electrical channels integrated therewith. As used herein, the term electrical channel generally refers to a multi-trace path, e.g., copper traces, of a network switch board configured to facilitate an electrical connection between two components or devices, e.g., connectors and microchips. For example, an electrical channel can be a multi-trace electrical connection between a host channel adapter board and a network switch by way of copper cables.

FIG. 1 is a perspective view of an example of a prior top rack network switch device 100. In the example, the network switch device 100 has a housing 102 and includes multiple connectors, including but not limited to a row of input/output (I/O) connectors 110-125, that are all spatially positioned substantially within a single plane, e.g., integrated with or otherwise associated with a single face 103 of the housing 102. The multiple connectors are also all in substantially the same orientation, e.g., facing perpendicularly outward from the housing 102.

FIG. 2 is a block diagram illustrating electrical connections of a prior network switch board 200 positioned within the network switch device 100 illustrated by FIG. 1. In the example, a multi-port network switch chip 204 is soldered on or otherwise integrated with a printed circuit board (PCB) 202. A number of high speed ports are routed as groups of copper traces 210-225 on the PCB 202 that serve to provide electrical connections between the network switch chip 204 and corresponding I/O connectors 110-125 that, as noted above, are all positioned at the same edge 103 of the PCB 202 [at the face 103 of the housing 102] and in substantially the same orientation. The physical layout and orientation of the network switch board 200 is typical of prior network switches in that the physical length of each of the traces in the groups of traces 210-225 on the PCB 202 is highly dependent on the location of the corresponding I/O connector. And, as noted above, the I/O connectors 110-125 are all positioned at, on, or otherwise near the same edge 103 of the PCB, thus putting them all in substantially the same plane.

In prior network switches, traces to I/O connectors that are positioned further out from a centrally located switch chip are generally longer than traces to centrally located I/O connectors. In the example, certain groups of traces 210-213 and 220-225 connect with I/O connectors 110-113 and 122-125 that are positioned further out from the network switch chip 204 are longer than other traces 214-221 that connect with more centrally-located I/O connectors 114-121. Longer traces generally result in higher insertion loss, which typically leads to non-compliance with insertion loss allocation budgets, thus negatively affecting the signal integrity of corresponding high speed channels.

As data signal rates within network switch boards continue to rise, concerns about insertion loss for electrical channels therein greatly increase. Indeed, speeds now extend into the hundreds of gigahertz (GHz) in data center applications.

### BRIEF DESCRIPTION OF THE DRAWINGS

Embodiments of the disclosed technology are illustrated by way of example, and not by way of limitation, in the drawings and in which like reference numerals refer to similar elements.

FIG. 1 is a perspective view of an example of a prior top rack network switch device.

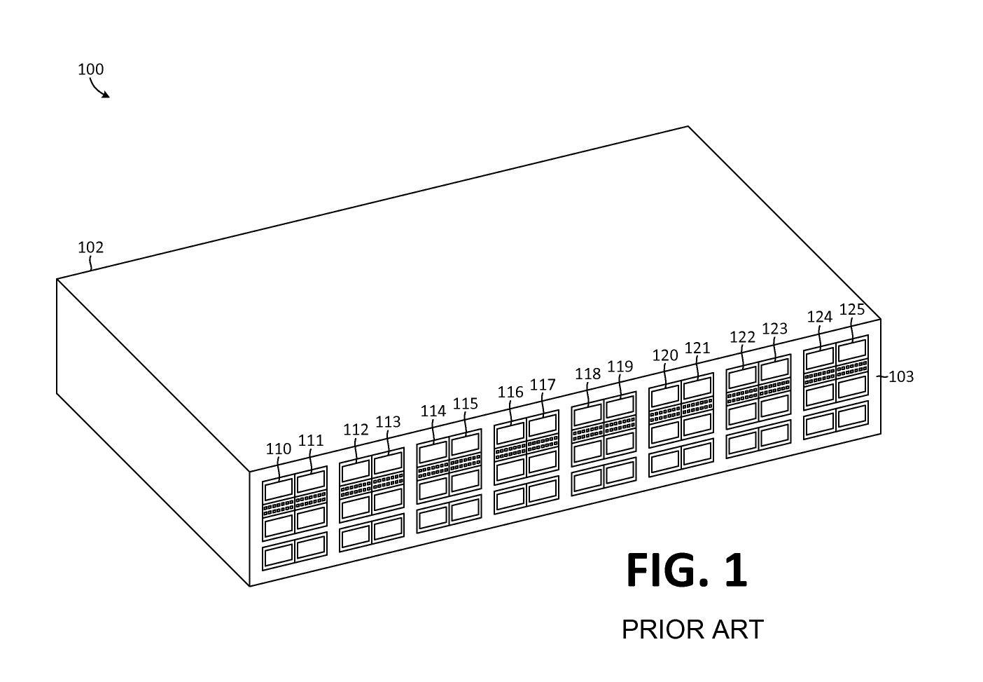

FIG. 2 is a block diagram illustrating electrical connections of a prior network switch board positioned within the network switch device illustrated by FIG. 1.

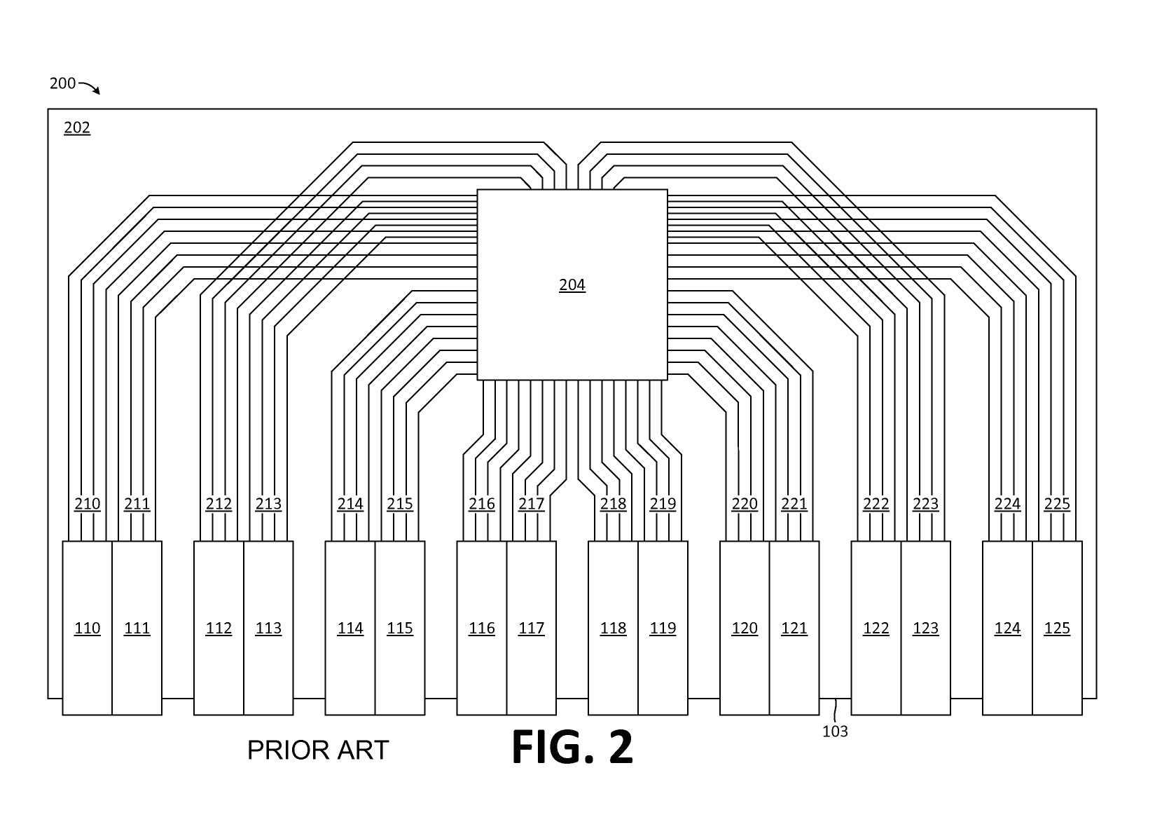

FIG. 3 is a perspective view of a first example of a network switch device in accordance with certain embodiments of the disclosed technology.

FIG. 4 is a block diagram illustrating a first example of electrical connections of a network switch board positioned within the network switch device illustrated by FIG. 3.

FIG. 5 is a perspective view of a second example of a network switch device in accordance with certain embodiments of the disclosed technology.

FIG. 6 is a block diagram illustrating a second example of electrical connections of a network switch board positioned within the network switch device illustrated by FIG. 5.

### DETAILED DESCRIPTION

Embodiments of the disclosed technology generally pertain to minimizing insertion loss for multi-port network switches. For example, certain input/output (I/O) connectors, or groupings of I/O connectors, connected to traces on a printed circuit board (PCB) and also integrated with or otherwise associated with the face plate of a chassis may be recessed respective to other I/O connectors (or groups of connectors) in order to reduce trace lengths and, thus, minimize insertion loss for those traces.

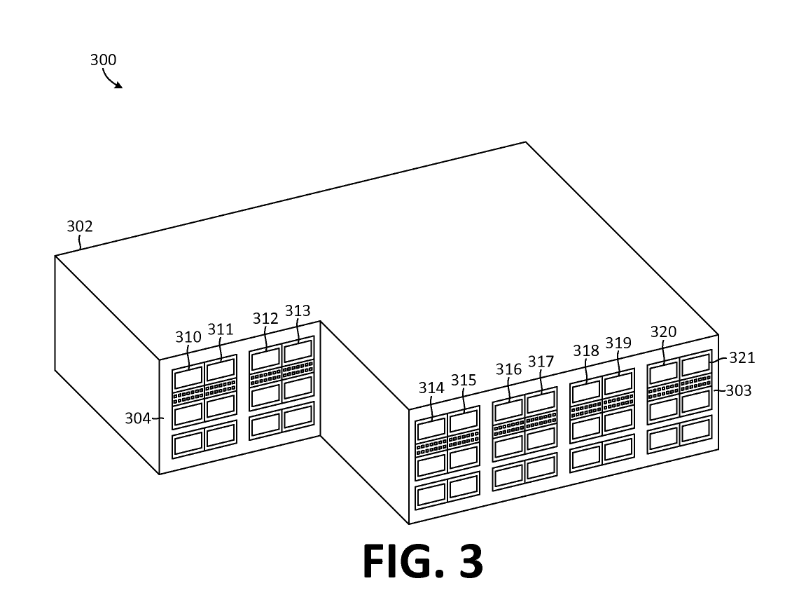

FIG. 3 is a perspective view of a first example of a network switch device 300 in accordance with certain embodiments of the disclosed technology. In the example, the network switch device 300 has a housing 302 and includes a first plurality of connectors, including input/output (I/O) connectors 310-313, that are all spatially positioned substantially within a first plane, e.g., integrated with or otherwise associated with a first face 304 of the housing 302.

The network switch device 300 also includes a second plurality of connectors, including I/O connectors 314-321, that are all spatially positioned substantially within a second plane, e.g., integrated with or otherwise associated with a second face 303 of the housing 302.

In the example, the first and second faces 303 and 304 [and, thus, the first and second planes] are at least substantially parallel to each other and separated by a certain distance, e.g., 1.5 inches or another suitable distance. In alternative embodiments, the first and second faces 303 and 304 [and, thus, the first and second planes] may be at a certain angle from each other, e.g., at 45 degrees from or perpendicular to each other.

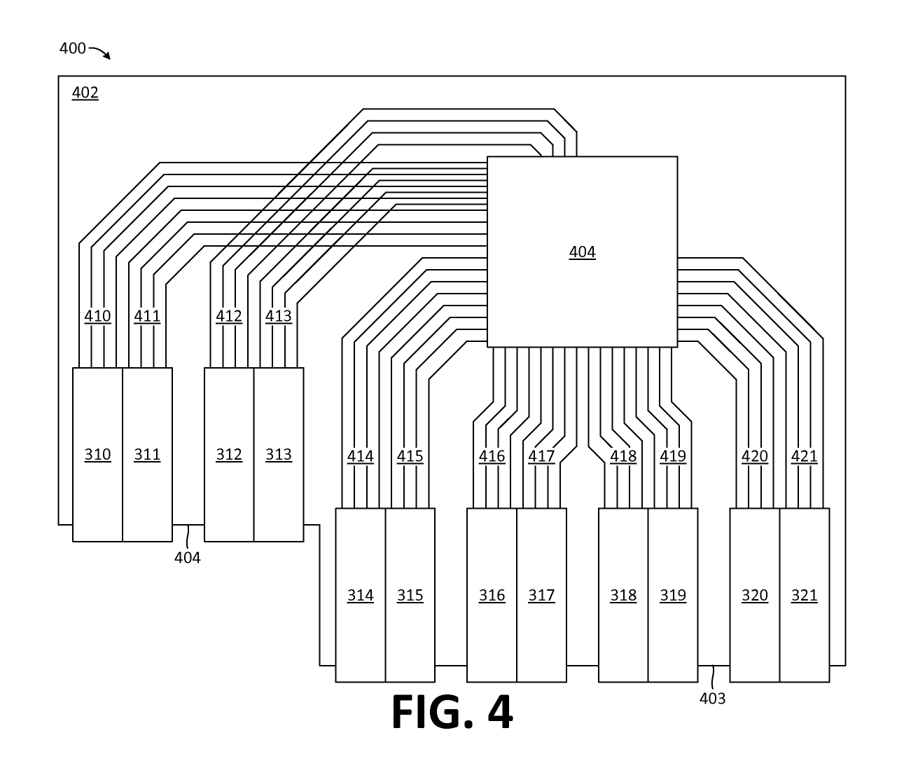

FIG. 4 is a block diagram illustrating a first example of electrical connections of a network switch board 400 positioned within the network switch device 300 illustrated by FIG. 3. In the example, a multi-port network switch chip 404 is soldered on or otherwise integrated with a printed circuit board (PCB) 402. A number of high speed ports are routed as groups of copper traces 410-421 on the PCB 402 that serve to provide electrical connections between the network switch chip 404 and corresponding I/O connectors 310-321.

In the example, the first plurality of I/O connectors 310-313 are all positioned at or otherwise integrated with a first edge 404 of the PCB 402 [which is positioned in close proximity to or at the first face 304 of the housing 302], while the second plurality of I/O connectors 314-321 are all positioned at a second edge 403 of the PCB 402 [which is positioned in close proximity to or at the second face 303 of the housing 302].

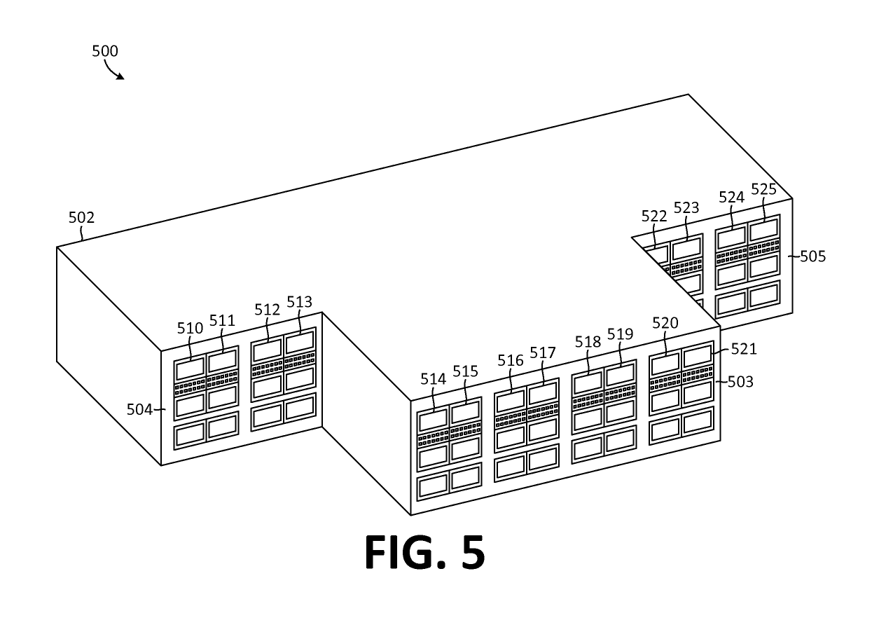

FIG. 5 is a perspective view of a second example of a network switch device 500 in accordance with certain embodiments of the disclosed technology. The network switch device 500 may be a top-of-rack (ToR) switch in a rack system, configured to connect to other various components in the rack system by way of cabling, for example. In alternative implementations, the network switch device 500 may be a switch in an individual blade server or on a motherboard or a network adapter card, for example.

In the example, the network switch device 500 has a housing 502 and includes a first plurality of connectors, including input/output (I/O) connectors 510-513, that are all spatially positioned substantially within a first plane, e.g., integrated with or otherwise associated with a first face 504 of the housing 502.

The network switch device 500 also includes a second plurality of connectors, including I/O connectors 514-521, that are all spatially positioned substantially within a second plane, e.g., integrated with or otherwise associated with a second face 503 of the housing 502.

The network switch device 500 also includes a third plurality of connectors, including I/O connectors 522-525, that are all spatially positioned substantially within a third plane, e.g., integrated with or otherwise associated with a second face 505 of the housing 502. In the example, the first and third planes are at least substantially the same; that is, the first and third faces 504 and 505 of the housing 502 are positioned substantially within the same plane.

In the example, the first and second faces 503 and 504 [and, thus, the first and second planes] are at least substantially parallel to each other and separated by a certain distance, e.g., 1.5 inches or another suitable distance. The second and third faces 503 and 505 [and, thus, the second and third planes] are also at least substantially parallel to each other and separated by a certain distance, e.g., 1.5 inches or another suitable distance. Any or all of the distances may be determined based on the tradeoffs between reduced trace length of the longer traces and useability thereof, e.g., the ability of and ease for users to plug cables into the recessed I/O ports.

In alternative embodiments, the first and second faces 503 and 504 [and, thus, the first and second planes] may be at a certain angle from each other, e.g., perpendicular to each other. Alternatively or in addition thereto, the second and third faces 503 and 505 [and, thus, the second and third planes] may be at a certain angle from each other, e.g., perpendicular to each other.

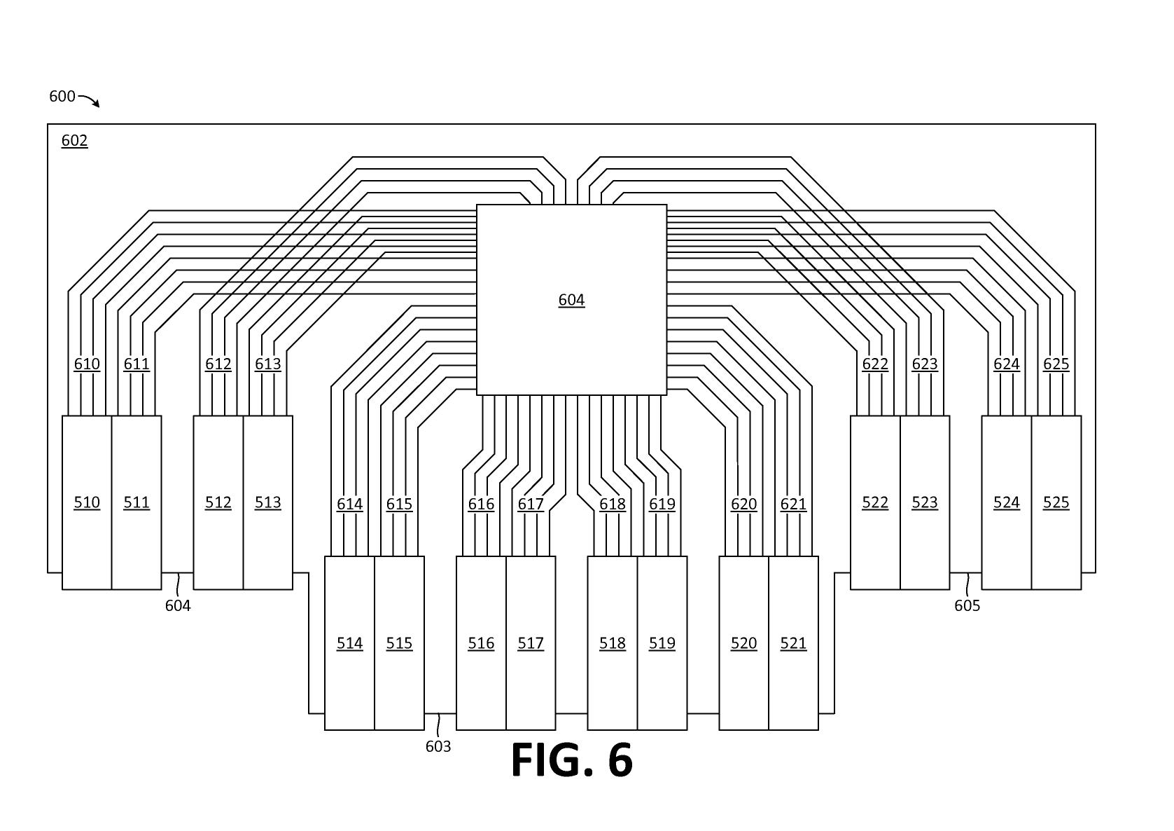

FIG. 6 is a block diagram illustrating a second example of electrical connections of a network switch board 600 positioned within the network switch device 500 illustrated by FIG. 5. In the example, a multi-port network switch chip 604 is soldered on or otherwise integrated with a printed circuit board (PCB) 602. A number of high speed ports are routed as groups of copper traces 610-625 on the PCB 602 that serve to provide electrical connections between the network switch chip 604 and corresponding I/O connectors 610-625.

In the example, the first plurality of I/O connectors 510-513 are all positioned at or otherwise integrated with a first edge 604 of the PCB 602 [which is positioned in close proximity to or at the first face 504 of the housing 502]. The second plurality of I/O connectors 514-521 are all positioned at a second edge 603 of the PCB 602 [which is positioned in close proximity to or at the second face 503 of the housing 502]. The third plurality of I/O connectors 522-525 are all positioned at a third edge 605 of the PCB 602 [which is positioned in close proximity to or at the third face 505 of the housing 502].

It will be appreciated that, in other network switch device embodiments, virtually any number of pluralities of connectors may be used in any of a wide number of arrangements and orientations. For example, certain network switch devices may have more than three faces and, thus, more than three corresponding edges of a PCB that are each directed outward from an electrical component, e.g., microchip, on the PCB in different directions. Alternatively or in addition thereto, multiple PCBs may be implemented, e.g., to further increase the number of PCB edges and, thus, faces on the housing of the device. For example, the I/O ports could be implemented at multiple sides of the switch device, e.g., not just at a front side but at the front side and also a back side and, in certain implementations, at a left side and/or right side as well.

Recessing long trace I/O ports and thus minimizing insertion loss on a network switch board may advantageously help to achieve longer-reach I/O copper cables, which may in turn help to reduce high performance computing (HPC) cluster interconnect cost, e.g., by avoiding having to use optical cables, which allow longer interconnects; otherwise, copper cable reach may be limited. For example, in one embodiment, reducing the trace length by 1.5 inches can reduce the insertion loss budget due to the PCB trace to allow for an increase in the copper cable attaching to an I/O port by 8-10″ without any reduction in the total insertion loss. Thus, users can use longer copper cables to connect to the network switch device without having to resort to less lossy, more expensive external interconnect options, such as optical cables. The depth of I/O connector recess may be directly proportional to the length reduction of the corresponding high speed trace on the board, though maximum recess depth may be limited by ability to access the recessed ports during I/O cable installation or removal.

In certain implementations, a rack system may include a housing, a PCB mounted within the housing, and at least one other component mounted within the housing, an outermost edge of the at least one other component spatially positioned substantially within a first plane. The rack system may also include a network switch chip integrated with the PCB, a first plurality of input/output (I/O) connectors integrated with a first face of the housing and spatially positioned substantially in parallel to each other within the first plane such that the first plurality of I/O connectors are substantially flush with the outermost edge of the at least one other component, and a first plurality of traces integrated with the PCB and configured to provide a first electrical channel between the network switch chip and the first plurality of I/O connectors. The rack system may also include a second plurality of I/O connectors integrated with a second face of the housing and spatially positioned substantially in parallel to each other within a second plane that is recessed from the first plane, and a second plurality of traces integrated with the PCB and configured to provide a second electrical channel between the network switch chip and the second plurality of I/O connectors.

Embodiments of the disclosed technology may be incorporated in various types of architectures. For example, certain embodiments may be implemented as any of or a combination of the following: one or more microchips or integrated circuits interconnected using a motherboard, a graphics and/or video processor, a multicore processor, hardwired logic, software stored by a memory device and executed by a microprocessor, firmware, an application specific integrated circuit (ASIC), and/or a field programmable gate array (FPGA). The term “logic” as used herein may include, by way of example, software, hardware, or any combination thereof.

Although specific embodiments have been illustrated and described herein, it will be appreciated by those of ordinary skill in the art that a wide variety of alternate and/or equivalent implementations may be substituted for the specific embodiments shown and described without departing from the scope of the embodiments of the disclosed technology. This application is intended to cover any adaptations or variations of the embodiments illustrated and described herein. Therefore, it is manifestly intended that embodiments of the disclosed technology be limited only by the following claims and equivalents thereof.

The following examples pertain to additional embodiments of technologies disclosed herein:

Example 1. An electrical device for facilitating transmission of electrical signals can include a printed circuit board (PCB), an electrical component integrated with the PCB, a first plurality of connectors integrated with a first edge of the PCB and spatially positioned substantially in parallel to each other within a first plane, a first plurality of traces integrated with the PCB and configured to provide a first electrical channel between the electrical component and the first plurality of connectors, a second plurality of connectors integrated with a second edge of the PCB and spatially positioned substantially in parallel to each other within a second plane that is distinct from the first plane, and a second plurality of traces integrated with the PCB and configured to provide a second electrical channel between the electrical component and second plurality of connectors.

Example 2. An electrical device for facilitating transmission of electrical signals can include a printed circuit board (PCB), an electrical component integrated with the PCB, a first plurality of connectors integrated with a first edge of the PCB and spatially positioned substantially in parallel to each other within a first plane, a first plurality of traces integrated with the PCB and configured to provide a first electrical channel between the electrical component and the first plurality of connectors, a second plurality of connectors integrated with a second edge of the PCB and spatially positioned substantially in parallel to each other within a second plane that is distinct from the first plane, a second plurality of traces integrated with the PCB and configured to provide a second electrical channel between the electrical component and second plurality of connectors, a third plurality of connectors integrated with a third edge of the PCB and spatially positioned substantially in parallel to each other within a third plane that is distinct from the first plane, and a third plurality of traces integrated with the PCB and configured to provide a third electrical channel between the electrical component and the third plurality of connectors.

Example 3. A rack system can include a housing, a printed circuit board (PCB) mounted within the housing, at least one other component mounted within the housing, an outermost edge of the at least one other component spatially positioned substantially within a first plane, a network switch chip integrated with the PCB, a first plurality of input/output (I/O) connectors integrated with a first face of the housing and spatially positioned substantially in parallel to each other within the first plane such that the first plurality of I/O connectors are substantially flush with the outermost edge of the at least one other component, a first plurality of traces integrated with the PCB and configured to provide a first electrical channel between the network switch chip and the first plurality of I/O connectors, a second plurality of I/O connectors integrated with a second face of the housing and spatially positioned substantially in parallel to each other within a second plane that is recessed from the first plane, and a second plurality of traces integrated with the PCB and configured to provide a second electrical channel between the network switch chip and the second plurality of I/O connectors.

Example 4. A rack system can include a housing, a printed circuit board (PCB) mounted within the housing, at least one other component mounted within the housing, an outermost edge of the at least one other component spatially positioned substantially within a first plane, a network switch chip integrated with the PCB, a first plurality of input/output (I/O) connectors integrated with a first face of the housing and spatially positioned substantially in parallel to each other within the first plane such that the first plurality of I/O connectors are substantially flush with the outermost edge of the at least one other component, a first plurality of traces integrated with the PCB and configured to provide a first electrical channel between the network switch chip and the first plurality of I/O connectors, a second plurality of I/O connectors integrated with a second face of the housing and spatially positioned substantially in parallel to each other within a second plane that is recessed from the first plane, a second plurality of traces integrated with the PCB and configured to provide a second electrical channel between the network switch chip and the second plurality of I/O connectors, a third plurality of I/O connectors integrated with a third face of the housing and spatially positioned substantially in parallel to each other within a third plane that is recessed from the first plane, and a third plurality of traces integrated with the PCB and configured to provide a third electrical channel between the network switch chip and the third plurality of connectors.

What is claimed is:

1. An electrical device for facilitating transmission of electrical signals, the electrical device comprising:
a printed circuit board (PCB);
an electrical component integrated with the PCB;
a first plurality of connectors integrated with a first edge of the PCB and spatially positioned substantially in parallel to each other within a first plane;
a first plurality of traces integrated with the PCB and configured to provide a first electrical channel between the electrical component and the first plurality of connectors;
a second plurality of connectors integrated with a second edge of the PCB and spatially positioned substantially in parallel to each other within a second plane that is distinct from the first plane; and
a second plurality of traces integrated with the PCB and configured to provide a second electrical channel between the electrical component and second plurality of connectors.

2. The electrical device of claim 1, wherein the electrical component is a network switch chip.

3. The electrical device of claim 1, wherein either or both of the first and second pluralities of connectors are input/output (I/O) connectors.

4. The electrical device of claim 1, wherein either or both of the first and second pluralities of traces are copper traces on the PCB.

5. The electrical device of claim 1, wherein the first and second planes are separated by a distance of 1.5 inches.

6. The electrical device of claim 1, further comprising:
a third plurality of connectors integrated with a third edge of the PCB and spatially positioned substantially in parallel to each other within a third plane that is distinct from the first plane; and
a third plurality of traces integrated with the PCB and configured to provide a third electrical channel between the electrical component and the third plurality of connectors.

7. The electrical device of claim 6, wherein the first and third planes are separated by a distance of 1.5 inches.

8. A network switch apparatus, comprising:
a housing;
a printed circuit board (PCB) mounted within the housing;
a network switch chip integrated with the PCB;
a first plurality of input/output (I/O) connectors integrated with a first face of the housing and spatially positioned substantially in parallel to each other within a first plane;
a first plurality of traces integrated with the PCB and configured to provide a first electrical channel between the network switch chip and the first plurality of I/O connectors;
a second plurality of I/O connectors integrated with a second face of the housing and spatially positioned substantially in parallel to each other within a second plane that is distinct from the first plane; and
a second plurality of traces integrated with the PCB and configured to provide a second electrical channel between the network switch chip and the second plurality of I/O connectors.

9. The network switch apparatus of claim 8, wherein either or both of the first and second pluralities of traces are copper traces on the PCB.ng

10. The network switch apparatus of claim 8, wherein the first and second planes are separated by a distance of 1.5 inches.

11. The network switch apparatus of claim 8, further comprising:
a third plurality of I/O connectors integrated with a third face of the housing and spatially positioned substantially in parallel to each other within a third plane that is distinct from the first plane; and
a third plurality of traces integrated with the PCB and configured to provide a third electrical channel between the network switch chip and the third plurality of connectors.

12. The network switch apparatus of claim 11, wherein the first and third planes are separated by a distance of 1.5 inches.

13. The network switch apparatus of claim 11, wherein the second and third planes are the same plane.

14. A rack system, comprising:
a housing;
a printed circuit board (PCB) mounted within the housing;
at least one other component mounted within the housing, an outermost edge of the at least one other component spatially positioned substantially within a first plane;
a network switch chip integrated with the PCB;
a first plurality of input/output (I/O) connectors integrated with a first face of the housing and spatially positioned substantially in parallel to each other within the first plane such that the first plurality of I/O connectors are substantially flush with the outermost edge of the at least one other component;
a first plurality of traces integrated with the PCB and configured to provide a first electrical channel between the network switch chip and the first plurality of I/O connectors;
a second plurality of I/O connectors integrated with a second face of the housing and spatially positioned substantially in parallel to each other within a second plane that is recessed from the first plane; and
a second plurality of traces integrated with the PCB and configured to provide a second electrical channel between the network switch chip and the second plurality of I/O connectors.

15. The rack system of claim 14, wherein the first and second planes are separated by a distance of 1.5 inches.

16. The rack system of claim 14, further comprising:
a third plurality of I/O connectors integrated with a third face of the housing and spatially positioned substantially in parallel to each other within a third plane that is recessed from the first plane; and
a third plurality of traces integrated with the PCB and configured to provide a third electrical channel between the network switch chip and the third plurality of connectors.

17. The net rack system of claim 16, wherein the first and third planes are separated by a distance of 1.5 inches.

18. The rack system of claim 16, wherein the second and third planes are the same plane.
